(19) United States
(12) Patent Application Publication
(10) Pub. No.: US 2006/0223268 A1
(43) Pub. Date: Oct. 5, 2006

(54) Phase-change random access memory and process for producing same

(75) Inventors: Hiroshi Moriya, Kasumigaura-shi (JP); Tomio Iwasaki, Tsukuba-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Renesas Technology Corp., Tokyo (JP)

(21) Appl. No.: 11/329,990

(22) Filed: Jan. 10, 2006

(30) Foreign Application Priority Data
Mar. 30, 2005 (JP) 2005-097851

(51) Int. Cl. H01L 21/336; H01L 27/12; H01L 21/4763; H01L 27/01; H01L 31/0392

(52) U.S. Cl. 438/288; 438/618; 257/350

(57) ABSTRACT

An object of the present invention is to provide a phase-change random access memory which hardly causes the peeling of a phase-change film in a production process. In the present invention, the surface of an insulating film around the phase-change film is positioned to a more substrate side than an interface between the insulating film and the phase-change film on the insulating film is.

### INCORPORATION BY REFERENCE

The present application claims priority from Japanese application JP2005-097851 filed on Mar. 30, 2005, the content of which is hereby incorporated by reference into this application.

### BACKGROUND OF THE INVENTION

The present invention relates to a phase-change random access memory.

In recent years, a phase-change random access memory (PRAM) using a phase-change chalcogenide material has been proposed as a next-generation nonvolatile semiconductor memory. A PRAM is anticipated to have a capability of writing onto and reading from the memory as rapidly as a DRAM (a dynamic random access memory) though having nonvolatility, can be integrated in a cell area equal to that of a flash memory, and accordingly is considered to be most predominant as a next-generation nonvolatile memory.

A chalcogenide material used in a PRAM has been already used in a DVD (a Digital Versatile Disc). The DVD makes use of such a property of the chalcogenide material that the reflectance of a reflected light from the chalcogenide material in an amorphous state is different from that in a crystal state, whereas the PRAM is a device for working as a memory by making use of such a property of the chalcogenide material that the electric resistance of a phase-change material in the amorphous state is different from that in the crystal state by several orders of magnitude.

A phase-change memory is switched; in other words, the phase of a phase-change material is converted from an amorphous state to a crystal state and on the reverse way by applying pulsed voltage to the phase-change material and using Joule heat generated at the time. When changing the phase of the phase-change material from the amorphous state to the crystal state, voltage is applied so that the phase-change material can be heated to a temperature between a crystallization temperature and a melting point. On the contrary, when changing the phase from the crystal state to the amorphous state, the phase-change material is heated to the melting point or higher by applied voltage with a short pulse and is quenched. For instance, a structure of a general PRAM is disclosed in FIG. 6 in Page 99 of a document, “Technology and Materials for Future Optical Memory” (electronic material—technology series, CMC Publishing CO., LTD., 2004). For an electrode film contacting with a phase-change film, a high melting metal such as tungsten or an alloy including tungsten is studied, which has resistance to the heat generated when switching the phase-change film. A bottom electrode is formed as a plug having a smaller area than the phase-change film has so that the phase-change film can switch its phase at a low current.

A phase-change film has inadequate adhesiveness to silicon oxide used for an insulation interlayer, and to an electrode film. For this reason, when a phase-change memory is produced, it tends to cause a problem that the phase-change film or the electrode film peels off. It leads to the lowering of a yield.

Accordingly, the first object of the present invention is to provide a phase-change random access memory having a memory structure of hardly causing peeling of a film.

The second object of the present invention is to provide such a phase-change random access memory as to be produced at a high yield.

The third object of the present invention is to provide a phase-change random access memory having high reliability.

The above described and other objects and a new feature of the present invention will become apparent in a description and attached drawings of the present specification.

### SUMMARY OF THE INVENTION

The outline of a representative aspect in the present invention disclosed in the present application will be now briefly described below.

(1) A process for producing a phase-change random access memory has the steps of:

(a) forming a bottom electrode embedded in an insulating film on a substrate;

(b) forming the phase-change film which has different specific resistance values from each other depending on the phase, on the insulating film so as to cover the bottom electrode;

(c) forming an electroconductive film on the phase-change film;

(d) etching the electroconductive film and forming a top electrode on the bottom electrode;

(e) after the step (d), removing the phase-change film existing around the top electrode by etching; and

(f) after the step (e), etching the film around the phase-change film so that the surface of the insulating film around the phase-change film can be located in a more substrate side than an interface between the insulating film and the phase-change film.

(2) An amount of the etched insulating film is 20 nm or more.

An effect provided by a representative aspect of the present invention disclosed in the present application will be now briefly described below.

A process for producing a phase-change random access memory according the present invention can inhibit the phase-change film from peeling, because the process can reduce the stress acting at the edge part of an interface between a phase-change film and an insulating film. Thereby, the present invention can provide a phase-change random access memory having a memory structure of hardly causing the peeling; the phase-change random access memory with high reliability; and the phase-change random access memory which can be produced at a high yield.

Other objects, features and advantages of the invention will become apparent from the following description of the embodiments of the invention taken in conjunction with the accompanying drawings.

### BRIEF DESCRIPTION OF DRAWINGS

FIG. 1 is a schematic sectional view showing a diagrammatic configuration of a memory cell equipped in a phase-change random access memory according to Embodiment 1 of the present invention;

FIG. 2 shows an equivalent circuit schematic of a memory cell in FIG. 1;

FIG. 3 is a schematic sectional view showing a process for producing a phase-change random access memory according to Embodiment 1 of the present invention;

FIG. 4 is a schematic sectional view showing a process for producing a phase-change random access memory, which follows FIG. 3;

FIG. 5 is a schematic sectional view showing a process for producing a phase-change random access memory, which follows FIG. 4;

FIG. 6 is a schematic sectional view showing a process for producing a phase-change random access memory, which follows FIG. 5;

FIG. 7 is a schematic sectional view showing a process for producing a phase-change random access memory, which follows FIG. 6;

FIG. 8 is a schematic sectional view showing a process for producing a phase-change random access memory, which follows FIG. 7;

FIG. 9 is a schematic sectional view showing a process for producing a phase-change random access memory, which follows FIG. 8;

FIG. 10 is a schematic sectional view showing a process for producing a phase-change random access memory, which follows FIG. 8 (FIG. 10(A) is a schematic sectional view, and FIG. 10(B) is an enlarged schematic sectional view of one part of FIG. 10(A));

FIG. 11 is a schematic sectional view showing a process for producing a phase-change random access memory, which follows FIG. 10;

FIG. 12 is a view showing an analysis result of normal stress acting on an interface between a phase-change film and an insulation interlayer, in a phase-change random access memory according to Embodiment 1 of the present invention;

FIG. 13 is a view showing an analysis result of shear stress acting on an interface between a phase-change film and an insulation interlayer, in a phase-change random access memory according to Embodiment 1 of the present invention;

FIG. 14 is a view showing the dependency of normal stress and shear stress acting on an interface between a phase-change film and an insulation interlayer, on an etched amount of the insulation interlayer, in a phase-change random access memory according to Embodiment 1 of the present invention;

FIG. 15 is a view for describing an operating pulse for a phase-change random access memory according to Embodiment 1 of the present invention;

FIG. 16 is a view for describing a temperature history when the phase-change random access memory according to Embodiment 1 of the present invention is operated;

FIG. 17 is a view showing the result of having analyzed the relationship between a plug diameter and the thickness (GST thickness) of a phase-change film by variously changing them in a phase-change random access memory according to Embodiment 1 of the present invention, and showing the dependency of normal stress acting around the edge part of the interface between the phase-change film and an insulation interlayer, on an etched amount of the insulation interlayer;

FIG. 18 is a view showing the result of having analyzed the relationship between a plug diameter and the thickness (GST thickness) of a phase-change film by variously changing them in a phase-change random access memory according to Embodiment 1 of the present invention, and showing the dependency of shear stress acting around the edge part of the interface between the phase-change film and an insulation interlayer, on an etched amount of the insulation interlayer;

FIG. 19 is a view showing standardized values of stress values in FIG. 17 by matching them to the maximum stress (stress at an overetched amount d=0);

FIG. 20 is a view showing standardized values of stress values in FIG. 18 by matching them to the maximum stress (stress at an overetched amount d=0);

FIG. 21 is a schematic sectional view showing a process for producing a phase-change random access memory according to Embodiment b 2 of the present invention;

FIG. 22 is a schematic sectional view showing a process for producing a phase-change random access memory, which follows FIG. 21;

FIG. 23 is a schematic sectional view showing a process for producing a phase-change random access memory, which follows FIG. 22;

FIG. 24 is a schematic sectional view showing a process for producing a phase-change random access memory, which follows FIG. 23 (FIG. 24(A) is a schematic sectional view, and FIG. 24(B) is an enlarged schematic sectional view of one part of FIG. 24 (a)); and

FIG. 25 is a view showing the vicinity of a nonvolatile memory device extracted from FIG. 1, FIG. 25(A) shows a state after a memory has been erased, and FIG. 25(B) shows a state after a memory has been written.

### DETAILED DESCRIPTION OF THE INVENTION

In the next place, embodiments according to the present invention will be described in detail with reference to the accompanying drawings. In all drawings for use in describing embodiments according to the invention, components having the same function will be marked with the same code and will not be repeatedly described.

### Embodiment 1

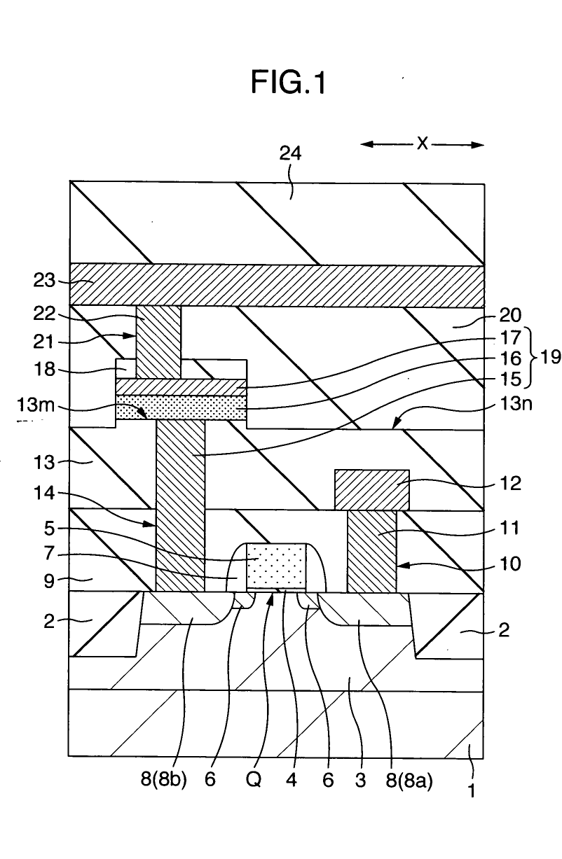

FIGS. 1 to 20 show a phase-change random access memory (a semiconductor device) in Embodiment 1 according to the present invention.

FIG. 1 is a schematic sectional view showing a diagrammatic configuration of a memory cell mounted in a phase-change random access memory;

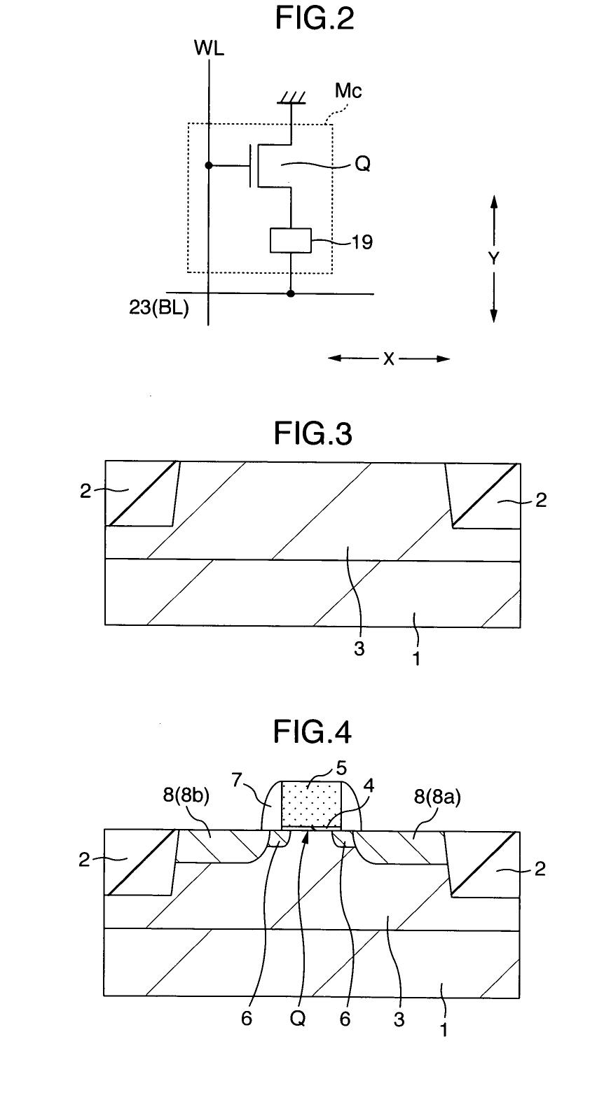

FIG. 2 is an equivalent circuit schematic of the memory cell;

FIGS. 3 to 11 are schematic sectional views showing a process for producing a phase-change random access memory;

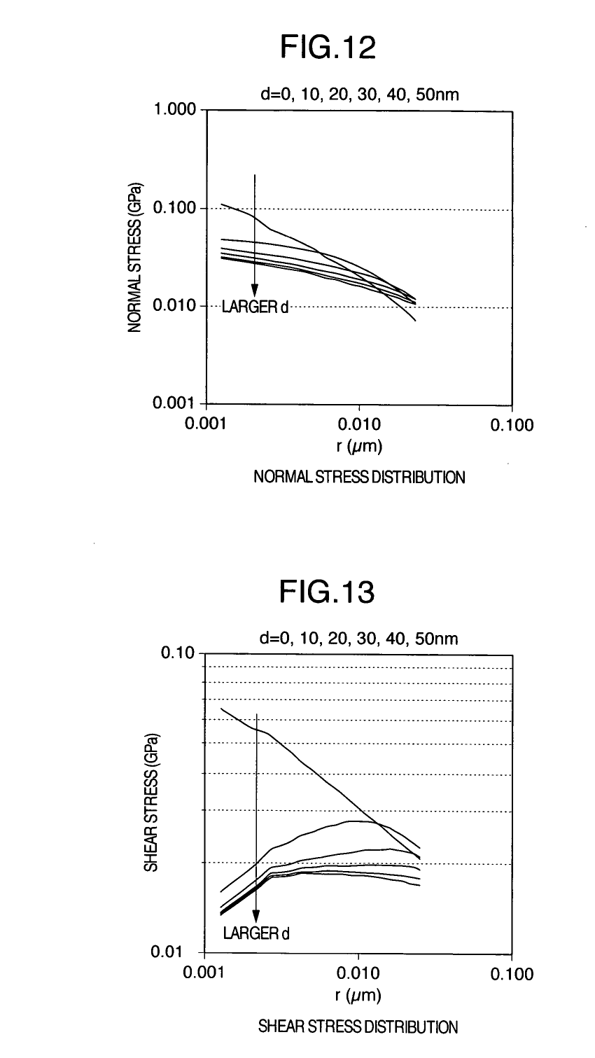

FIG. 12 is a view showing an analysis result of normal stress acting on an interface between a phase-change film and an insulation interlayer in an phase-change random access memory;

FIG. 13 is a view showing the analysis result of shear stress acting on an interface between a phase-change film and an insulation interlayer in a phase-change random access memory;

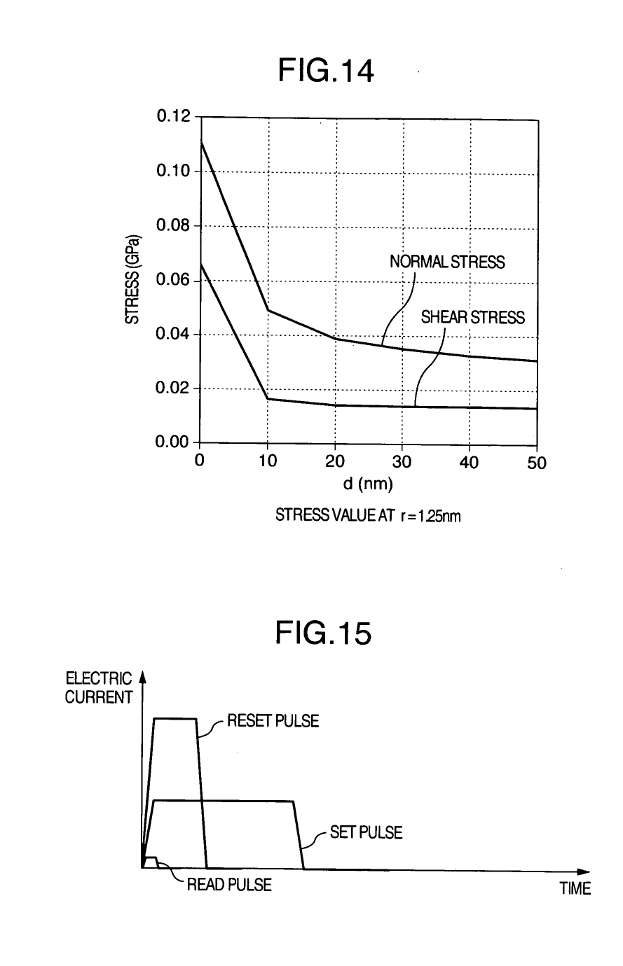

FIG. 14 is a view showing the dependency of normal stress and shear stress acting on an interface between a phase-change film and an insulation interlayer, on an etched amount of the insulation interlayer, in a phase-change random access memory;

FIG. 15 is a view for use in describing an operating pulse for a phase-change random access memory;

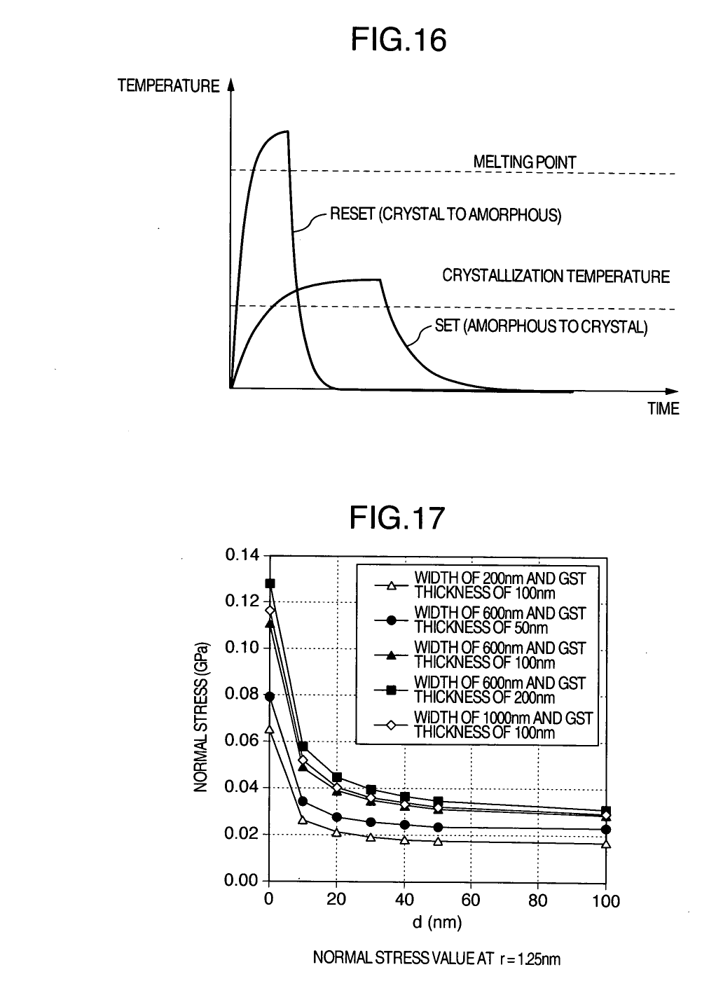

FIG. 16 is a view for use in describing a temperature history when the phase-change random access memory is operated;

FIG. 17 is a view showing the result of having analyzed the relationship between a plug diameter (the diameter of a bottom electrode) and the thickness (GST thicknesses) of a phase-change film by variously changing them in a phase-change random access memory, and showing the dependency of normal stress acting around the edge part of the interface between the phase-change film and an insulation interlayer, on an etched amount of the insulation interlayer;

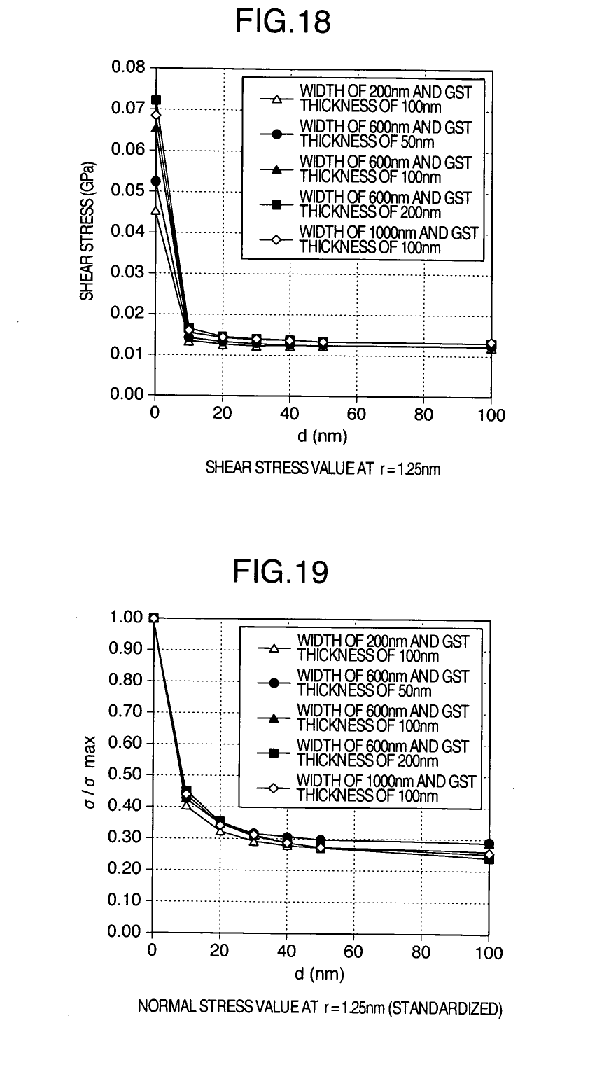

FIG. 18 is a view showing the result of having analyzed the relationship between a plug diameter (the diameter of a bottom electrode) and the thickness (GST thickness) of a phase-change film by variously changing them in a phase-change random access memory, and showing the dependency of shear stress acting around the edge part of the interface between the phase-change film and an insulation interlayer, on an etched amount of the insulation interlayer;

FIG. 19 is a view showing standardized values of stress values in FIG. 17 by matching them to the maximum stress (stress at an overetched amount d=0); and

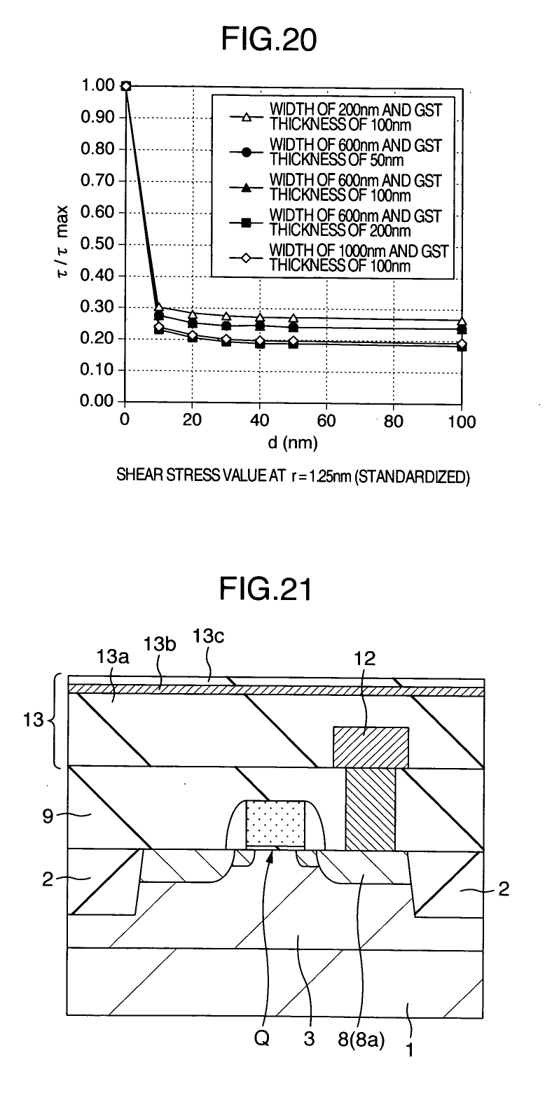

FIG. 20 is a view showing standardized values of stress values in FIG. 18 by matching them to the maximum stress (stress at an overetched amount d=0).

A phase-change random access memory according to the present embodiment 1 has a configuration having a memory cell array in which a plurality of memory cells Mc shown in FIG. 2 are arranged in a matrix form. The memory cell Mc has the configuration as shown in FIG. 2, having one nonvolatile memory device 19 and a transistor for controlling (for instance, a MISFET (Metal Insulator Semiconductor Field Effect Transistor)-Q), which are serially connected, and is arranged in an intersection of a bit line 23 extending in an X-direction and a word WL extending in a Y-direction (a direction perpendicular to the X-direction in the same plane).

A phase-change random access memory according to the present embodiment 1, as shown in FIG. 1, is mainly composed of a semiconductor substrate (hereafter simply called a substrate), for instance, a p-type silicon substrate 1 consisting of single crystal silicon.

A principal plane (an element-formed plane and a circuit-formed plane) of a substrate 1 has an element-forming region partitioned by element isolation regions 2, and in the element-forming region, a p-type well region 3 and a MISFET-Q of a transistor for controlling a memory cell Mc are formed.

An element isolation region 2 is, for instance, formed of a shallow-groove isolation region (SGI: shallow groove isolation, or STI; shallow trench isolation), though not being limited to it. The shallow groove isolation region is formed by forming the shallow groove on a principal plane of a substrate 1 and then selectively embedding an insulating film (for instance, made of silicon oxide) in the shallow groove.

A MISFET-Q is composed of, for instance, an n-channel conductivity type and has a configuration mainly consisting of a channel region, a gate insulation film 4, a gate electrode 5, a source region and a drain region. The gate insulation film 4 is made of, for instance, silicon oxide, and is arranged on an element-forming region of a principal plane of a substrate 1. The gate electrode 5 is made of, for instance, a silicon film having impurities for decreasing an ohmic value doped therein, and is arranged on the element-forming region of the principal plane of the substrate 1 through the gate insulation film 4. The channel region is provided on the surface layer of the substrate 1 right under the gate electrode 5. The source region and the drain region are arranged in the surface layer of the substrate 1 so as to sandwich the channel region, in a longitudinal direction of the channel (a longitudinal direction of the gate) in the channel region.

A source region and a drain region have a configuration having a pair of n-type semiconductor regions 6 that are extended regions and a pair of n-type semiconductor regions 8 (8a and 8b) that are contact regions. The n-type semiconductor region 6 is arranged in the element-forming region of a principal plane of a substrate 1, so as to conform to a gate electrode 5. The n-type semiconductor region 8 is arranged in the element-forming region of the principal plane of the substrate 1, so as to conform to a sidewall spacer 7 formed on a side wall of the gate electrode 5. The sidewall spacer 7 is formed of, for instance, a silicon oxide film.

Here, a MISFET is one type of an insulation gate type field effect transistor, and includes a field effect transistor having a gate electrode formed of an electroconductive material other than metal. In addition, a field effect transistor having a gate insulation film formed of a silicon oxide film is called a MOSFET (Metal Oxide Semiconductor Field Effect Transistor).

On a principal plane of a substrate 1, interlayer insulation films 9 and 13 are provided so as to cover a MISFET-Q. The interlayer insulation films 9 and 13 are made of, for instance, a BPSG (boron doped phospho silicate glass) film, a SOG (spin on glass) film, or a silicon oxide film or a nitride film formed with a chemical vapor deposition (CVD) method or a sputtering method.

Between interlayer insulation films 9 and 13 (on the interlayer insulation film 9), a wire 12 extending in an X-direction is arranged. On the interlayer insulation film 13, a nonvolatile memory device 19 of a memory cell Mc is arranged, and then the interlayer insulation film 20 is arranged so as to cover the nonvolatile memory device 19. On the interlayer insulation film 20, a bit line 23 extending in the X-direction is arranged, and then the interlayer insulation film 24 is arranged so as to cover the bit line 23.

On one n-type semiconductor region 8a connected to a MISFET-Q, a connection hole 10 reaching an n-type semiconductor region 8a from the surface of an interlayer insulation film 9 is arranged, and in the connection hole 10, an electroconductive plug 11 is embedded. On the other n-type semiconductor region 8b connected to the MISFET-Q, a connection hole 14 reaching the n-type semiconductor region 8b from the surface of the interlayer insulation film 13 is arranged, and in the connection hole 14, an electroconductive plug 15 is embedded. The electroconductive plugs 11 and 15 are composed of a neighboring electroconductive film for preventing the diffusion of impurities in the semiconductor region made of, for instance, titanium nitride (TiN), and a main electroconductive film coated with the neighboring electroconductive film.

A nonvolatile memory device 19 in a memory cell Mc is composed so as to use an electroconductive plug 15 embedded in interlayer insulation films (13 and 9) as a bottom electrode, and accordingly has a configuration having the bottom electrode 15, a phase-change film 16 arranged on the interlayer insulation film 13 so as to cover the bottom electrode 15 and a top electrode 17 arranged on the above described phase-change film 16 so as to cover the phase-change film 16. Specifically, the nonvolatile memory device 19 has a stacked structure consisting of the bottom electrode (15), the phase-change film 16 layered thereon and the top electrode 17 further layered thereon. The phase-change film 16 can assume different specific resistance values from each other depending on the phase, and is made of, for instance, a germanium-antimony-tellurium compound (Ge₂Sb₂Te₅). The top electrode 17 is made of the film of, for instance, tungsten (W) of a high-melting metal. The top electrode 17 is covered with an insulating film 18 made of, for instance, a silicon oxide film.

On the top electrode 17 of a nonvolatile memory device 19, a connection hole 21 reaching a top electrode 17 from the surface of an interlayer insulation film 20 is arranged, and in the connection hole 21, an electroconductive plug 22 made of, for instance, tungsten (W) is embedded.

One n-type semiconductor region 8a of a MISFET-Q is electrically connected to a wire 12 extending on an interlayer insulation film 9 through an electroconductive plug 11. The other n-type semiconductor region 8b of the MISFET-Q is electrically connected to a phase-change film 16 of a nonvolatile memory device 19 arranged on the interlayer insulation film 13, through the electroconductive plug 15 (the bottom electrode of the nonvolatile memory device 19). A top electrode 17 of the nonvolatile memory device 19 is electrically connected to a bit line 23 extending on the interlayer insulation film 20, through an electroconductive plug 22. To a wire 12, a voltage of, for instance, 0 [V] is applied as reference voltage.

Here, the bottom electrode (15) of a nonvolatile memory device 19 is formed into a smaller flat area than that of a phase-change film 16, so as to switch the phase of the phase-change film 16 at a low current. Accordingly, the nonvolatile memory device 19 has a structure in which the phase-change film 16 contacts with an interlayer insulation film 13. Such a structure tends to cause a problem that the phase-change film 16 peels off, because stress concentrates in the vicinity of the edge part of an interface 13m between the interlayer insulation film 13 and the phase-change film 16, due to a difference of a coefficient of linear expansion between the interlayer insulation film 13 and the phase-change film 16, and besides the phase-change film 16 has inadequate adhesiveness to silicon oxide used as the interlayer insulation film.

For this reason, the present inventors attempted to reduce stress concentrating in the vicinity of the edge part of an interface 13m between an interlayer insulation film 13 and a phase-change film 16, for the purpose of inhibiting the peeling of the phase-change film 16 having inadequate adhesiveness to the interlayer insulation film. The stress can be reduced by offsetting (positioning) the surface 13n which is a part of the interlayer insulation film 13 and locates around the phase-change film 16 to a more substrate 1 side in a thickness direction than the surface (the interface 13m) which is a part of the interlayer insulation film 13 and is covered with the phase-change film 16, out of the surface (the upper surface) of the interlayer insulation film 13, in other words, by forming a step. In the present-embodiment 1, as shown in FIG. 1, the surface 13n around the phase-change film 16 in a part of the interlayer insulation film 13 is positioned to a more substrate 1 side than the surface (interface 13m) covered the phase-change film 16 in a part of the interlayer insulation film 13 is, and the surface 13n around the phase-change film 16 in a part of the interlayer insulation film 13 is formed so as to conform a periphery of the phase-change film 16. The surface 13n of the interlayer insulation film 13 can be formed, for instance, by overetching the interlayer insulation film 13 when patterning the phase-change film 16 by etching.

In the next place, a process for producing a phase-change random access memory will be described with reference to FIGS. 3 to 11.

The production process includes the steps of: first of all, preparing a semiconductor substrate, for instance, a p-type silicon substrate (substrate 1) formed of single crystal silicon having a specific resistance of about 10 [Ωcm]; afterwards, forming an element isolation region 2 (cf. FIG. 3) for partitioning an element-forming region on a principal plane (an element-forming surface and a circuit-forming surface) of the substrate 1; and then selectively forming a p-type well regions 3 (cf. FIG. 3) on the element-forming region of the principal plane of the substrate 1. The element isolation region 2 is not limited to the following example, but is formed by the steps of: forming a shallow groove (for instance, a groove with a depth of about 300 [nm]) on the principal plane of the substrate 1; afterwards, forming an insulating film, for instance, made of a silicon oxide film, on the principal plane of the substrate 1 including the inside of the shallow groove with a CVD method; and then selectively removing the insulating film on the substrate 1 so that the above described insulating film remains in the shallow groove with a CMP (chemical mechanical polishing) method.

Subsequently, as shown in FIG. 4, a MISFET-Q is formed on the element-forming region of the principal plane of a substrate 1. The MISFET-Q is formed, for instance, by the steps of: forming a gate insulation film 4 made of a silicon oxide film on the element-forming region of the principal plane of the substrate 1, with a thermal oxidation method; afterwards, forming a polycrystalline silicon film on the whole principal plane of the substrate 1 including the gate insulation film 4, with a CVD method; then implanting ions of impurities in the above described polycrystalline silicon film, for the purpose of reducing an ohmic value; subsequently, patterning the above described polycrystalline silicon film to form a gate electrode 5 on the gate insulation film 4; afterwards, implanting ions of impurities (for instance, arsenic (As)) in the element-forming region of the principal plane of the substrate 1, to form a pair of n-type semiconductor regions 6 (extended regions) so as to conform to the gate electrode 5; subsequently, forming an insulating film made of a silicon oxide film on the whole principal plane of the substrate 1 including the gate electrode 5, with the CVD method; then etching the above described insulating film with an anisotropic etching technique such as RIE (reactive ion etching), to form a sidewall spacer 7 on a side wall of the gate electrode 5; and then implanting the ions of the impurities (for instance, arsenic (As)) in the element-forming region of the principal plane of the substrate 1, to form a pair of n-type semiconductor regions 8 (8a and 8b: contact regions) so as to conform to the sidewall spacer 7.

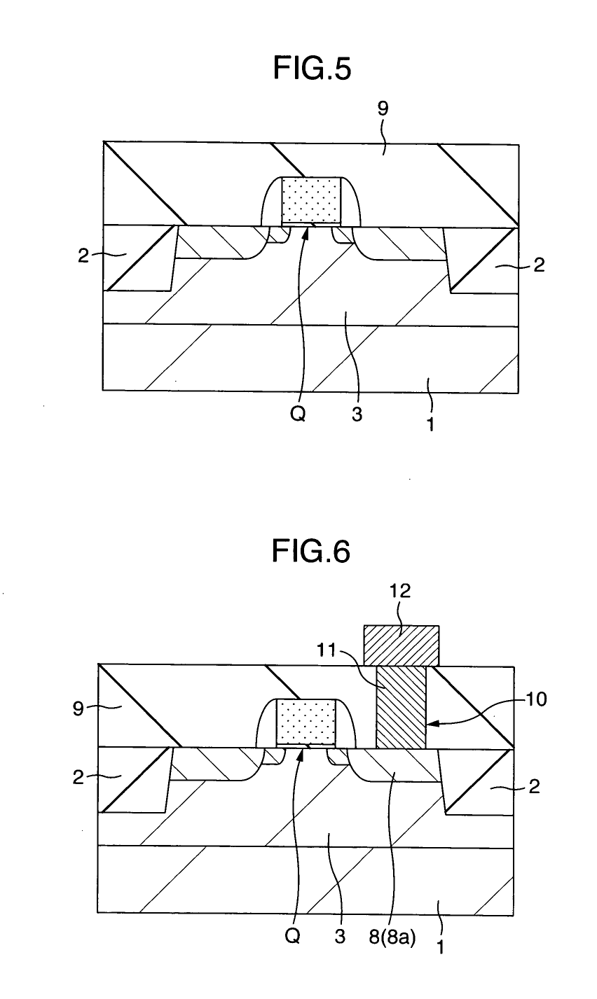

The production process subsequently continues the steps of: forming an interlayer insulation film 9, for instance, made of a BPSG film,.a SOG film, or a silicon oxide film, a nitride film or the like with a CVD method or a sputtering method, on the whole principal plane of a substrate 1 including the top surface of a MISFET-Q; and then, as shown in FIG. 5, flattening the surface of the interlayer insulation film 9, for instance, with a CMP method:

forming a connection hole 10 (cf. FIG. 6) reaching a n-type semiconductor region 8a from the surface of an interlayer insulation film 9 on one n-type semiconductor region 8a of a MISFET-Q; then, selectively embedding an electroconductive plug 11 (cf. FIG. 6) in the connection hole 10; and then, as shown in FIG. 6, forming a wire 12 electrically connected to the electroconductive plug 11, on the interlayer insulation film 9:

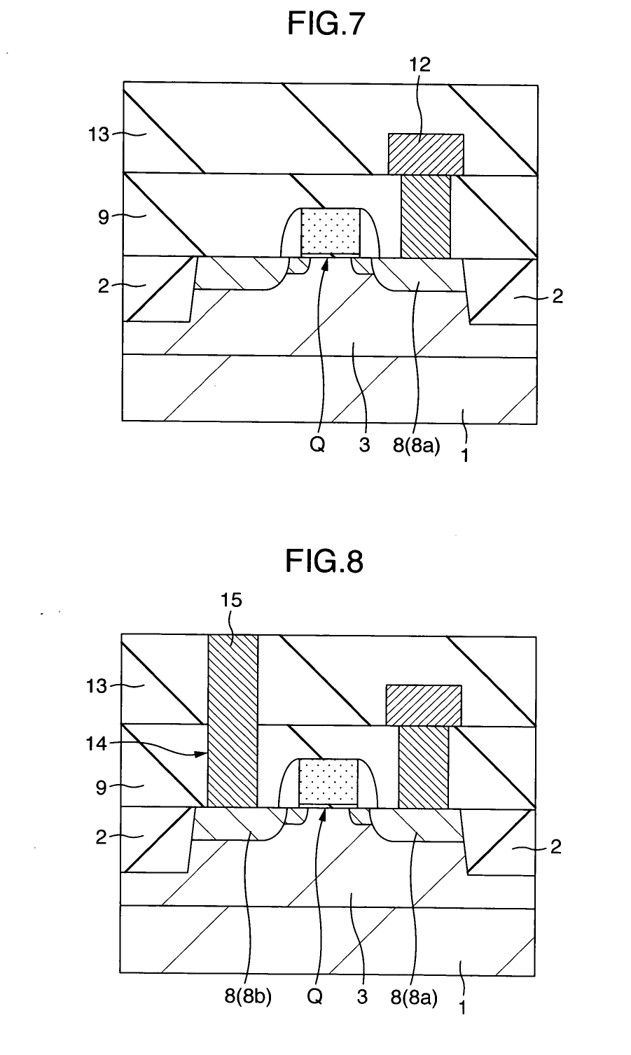

forming an interlayer insulation film 13 (cf. FIG. 7), for instance, made of a BPSG film, a SOG film, or a silicon oxide film, a nitride film or the like with a CVD method or a sputtering method, on an interlayer insulation film 9 so as to cover a wire 12; and then, as shown in FIG. 7, flattening the surface of the interlayer insulation film 13 with a CMP method;

forming a connection hole 14 (cf. FIG. 8) reaching a n-type semiconductor region 8b from the surface of an interlayer insulation film 13, on the other n-type semiconductor region 8b of a MISFET-Q; and then, as shown in FIG. 8, selectively embedding an electroconductive plug 15 in a connection hole 14:

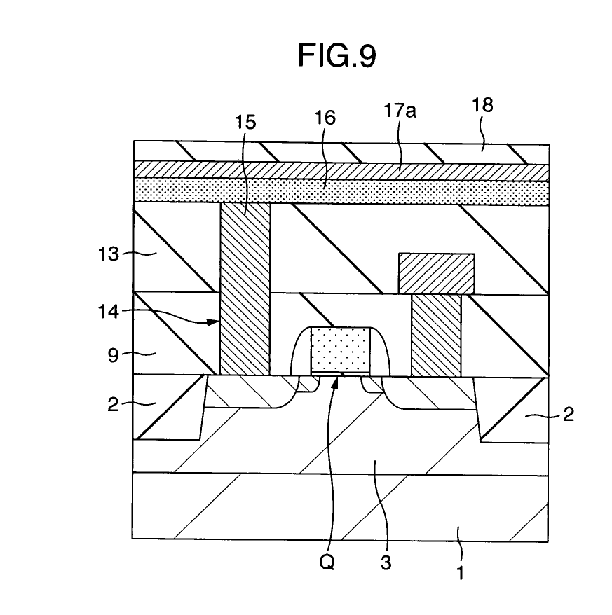

as shown in FIG. 9, sequentially forming a phase-change film 16 made of a germanium-antimony-tellurium compound (Ge₂Sb₂Te₅), for instance, with a sputtering method, a top electrode film 17a made of tungsten (W), for instance, with a sputtering method, and an insulating film 18 made of a silicon oxide film, for instance, with a CVD method, on an interlayer insulation film 13 including the top surface of an electroconductive plug 15: and then

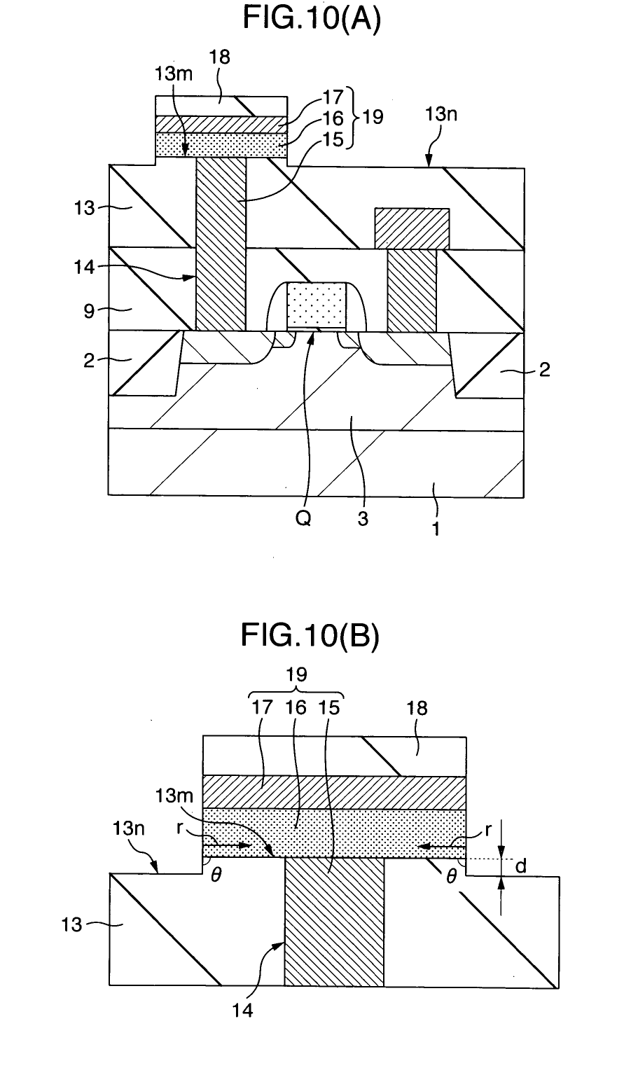

sequentially patterning an insulating film 18, a top electrode film 17a and a phase-change film 16, as shown in FIG. 10(A), with a dry etching technique. By the step, a nonvolatile memory device 19 is formed which has a bottom electrode made of an electroconductive plug 15 embedded in an interlayer insulation films (13 and 9), the phase-change film 16 provided on the interlayer insulation film 13 so as to cover the bottom electrode, and an top electrode 17 which is made of the top electrode film 17a, and arranged on the phase-change film 16 so as to cover the phase-change film 16.

An insulating film 18 is patterned by forming an etching mask on the insulating film 18, for instance, with a photolithographic technology, and then removing the insulating film 18 around an etching mask by etching. A top electrode film 17a is patterned by removing the top electrode film 17a around the patterned insulating film 18 by etching. The phase-change film 16 is patterned by removing the phase-change film 16 around the patterned top electrode film 17a (the top electrode) by etching.

Here, in the above described dry etching step, the surface of an interlayer insulation film 13 is overetched as shown in FIG. 10(B). An overetching amount d is, for instance, set to 20 [nm]. Then, because the interlayer insulation film 13 is overetched, a forming angle θ of the interlayer insulation film 13 at an edge part of an interface between the phase-change film 16 and an interlayer insulation film 9a becomes smaller than 180 degrees. In an example shown in FIG. 10(B), the above described forming angle θ is almost 90 degrees. As will be shown later, when the above described forming angle θ is smaller than 180 degrees or less, the stress acting around the edge part of the interface 13m between the interlayer insulation film 13 and the phase-change film 16 can be reduced, to inhibit the peeling of the phase-change film 16 (to improve the adhesion between them).

The present embodiment 1 adopts the method of etching the surface of the interlayer insulation film 13 around a phase-change film 16 when patterning the phase-change film 16, to overetch it, as a method of offsetting (positioning) the surface of the interlayer insulation film 13 around the phase-change film 16 to a position located to a more substrate 1 side than an interface 13m between the interlayer insulation film 13 and the phase-change film 16 is. Accordingly, the surface 13n after the interlayer insulation film 13 around the phase-change film 16 has been overetched, is formed so as to conform to a perimeter of the phase-change film 16.

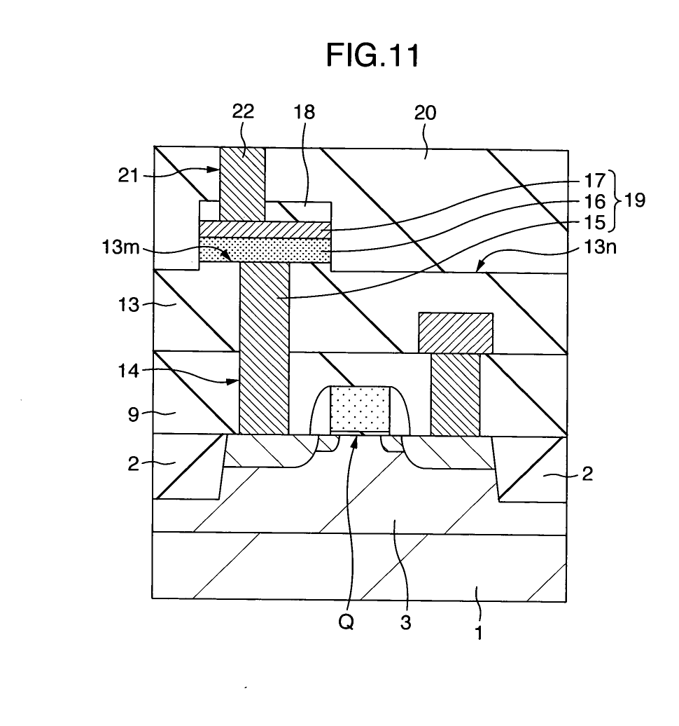

The production process subsequently continues the steps of: forming an interlayer insulation film 20 (cf. FIG. 11) on an interlayer insulation film 13 so as to cover a nonvolatile memory device 19, for instance, with a CVD method; afterwards, forming a connection hole 21 reaching a phase-change film 16 from the surface of the interlayer insulation film 20 on the phase-change film 16 of the nonvolatile memory device 19; and then, as shown in FIG. 11, selectively embedding an electroconductive plug 22 in the connection hole 21. The electroconductive plug 22 is formed of tungsten film-formed, for instance, with a sputtering method.

Subsequently, a bit line 23 which is electrically connected to an electroconductive plug 22 is formed on an interlayer insulation film 20, and then an interlayer insulation film 24 is formed on the interlayer insulation film 20 so as to cover the bit line 23. A structure shown in FIG. 1 is completed by the above steps.

In the next place, an effect of having reduced the stress forming around the edge part of an interface between an interlayer insulation film 13 and a phase-change film 16, by over-etching the interlayer insulation film 13 in a step shown in FIG. 10, will be described on the basis of a result of stress analysis with reference to the drawings.

FIGS. 12 and 13 respectively shows a result of having analyzed normal stress and shear stress acting around an edge part of an interface 13m between an interlayer insulation film 13 and a phase-change film 16. In the figures, r in an abscissa axis is a distance from the edge part, as is shown in FIG. 10(B).

The stresses were analyzed and determined in conditions of: a width of a nonvolatile memory device 19 of 600 [nm]; a thickness of a phase-change film 16 of 100 [nm]; a diameter of an electroconductive plug 15 (bottom electrode) of 160 [nm]; a thickness of a top electrode 17 of 50 [nm]; a thickness of an insulating film 18 of 50 [nm]; and over-etched amounts d of 0 [nm], 10 [nm], 20 [nm], 30 [nm], 40 [nm] and 50 [nm], which were five cases.

It is known from a measurement result that a stress of about 100 [MPa] remains in a phase-change film 16 when the film is formed, so that in the analysis, 100 [MPa] was used as a stress of the phase-change film in an early stage. Each stress of tungsten forming a top electrode 17 and a silicon oxide film forming an insulating film 18 in the early stage were set to 0 [MPa], because they can be adjusted by a film-forming condition.

It is understood from FIGS. 12 and 13 that normal stress and shear stress of an interface 13m between an interlayer insulation film 13 and a phase-change film 16 increases as the position approached to an edge part (r=0). The stress concentration is remarkable in the edge part particularly when an interlayer insulation film 13 is not overetched, or equivalently, d=0. The above stress concentration is considered to have induced the peeling of the phase-change film 16. In contrast to this, when the interlayer insulation film 13 is overetched, the stress concentration at the edge part is reduced.

FIG. 14 shows the dependency of normal stress and shear stress on an overetched amount d. A stress value when a distance from an edge part r=0.125 [μm] was used as a representative value of the stress value. It is clear from FIG. 14 that the normal stress and the shear stress decrease with the increase of an overetched amount d, and that both values of the normal stress and the shear stress when the overetched amount is 20 [nm] are reduced into about ⅓ of the values when not overetched. The stress concentration remarkably occurs when the overetched amount is 20 [nm] or less, so that a suitable over-etching amount is about 20 [nm] in order to reduce the stress with a small over-etching amount. In other words, the overetching for the interlayer insulation film 13 can reduce the stress concentration in the edge part of the interface 13m between the interlayer insulation film 13 and the phase-change film 16, and can inhibit the peeling of the phase-change film 16. Particularly, in order to increase an effect of the stress reduction, the overetching amount of the interlayer insulation film 13 is preferably 20 [nm] or more.

In the next place, a principle of operation of a phase-change random access memory according to the present invention will be described with reference to FIGS. 15 and 16.

A PRAM is a device which has applied a phase-change material used in a DVD storage medium to a semiconductor memory. The DVD storage medium records information, by changing the phase-change material to an amorphous state or a crystal state with a laser pulse, and using a difference of a refractive index between an amorphous state and a crystal state. On the other hand, the PRAM selects the amorphous state or the crystal state, by applying pulse voltage to a memory cell and adjusting a value of voltage and a period of pulsed time. An electric resistance in the amorphous state is different from that the crystalline state by 100 times or more, so that the PRAM records the information by using the difference of the resistance.

When switching (reset) the state of a phase-change film 16 to an amorphous state from a crystal state, a nonvolatile memory device 19 passes a short-time pulse (reset pulse) of a comparatively large current to the phase-change film 16, as shown in FIG. 15, and when switching (setting) the state of the phase-change film 16 to the crystal state from the amorphous state, it passes a long-time pulse (set pulse) of the comparatively small current. On the other hand, when reading the information, the nonvolatile memory device passes a small-current short-time pulse (lead pulse) to the phase-change film 16, and the information in a memory is read by using the difference of an ohmic value of the phase-change film 16. When the reset pulse is applied, the phase-change film 16 melts due to the passage of a large electric current, and then is rapidly cooled because of narrow pulse width to change into an amorphous state. On the other hand, when the set pulse is applied, it passes such a level of an electric current as to heat the phase-change film 16 to the temperature exceeding the crystallization temperature in the phase-change film 16, and thereby changes the state of the phase-change film 16 to the crystal state from the amorphous state (FIG. 16). For instance, when the phase-change film is made of Ge₂Sb₂Te₅ and has a thickness of 70 nm, and a plug contacting with the phase-change film has a diameter of 160 nm, it was confirmed that the device which had a resistance of about 30 kilo-ohm in a set state (in a crystal state for the phase-change film) is reset (changes the state of the phase-change film into an amorphous state) by a high-voltage short-pulse having a voltage of 2.8 [V] and a pulse width of 100 [nsec], and that the phase-change film in the amorphous state has the resistance of about 3 megaohm, which is 100 times higher than that in the crystal state. It was also confirmed that the device in a reset state (in the amorphous state for the phase-change film) is memory-set (changes the state of the phase-change film into the crystal state) by a low-voltage and long pulse having a voltage of 1.3 [V] and a pulse width of 1.2 [μsec]; that the phase-change film in the crystal state has the resistance of about 30 kilo-ohm; that the ohmic values in the reset state and the set state was stably repeated even when the memory is repeatedly overwritten, and while the memory is repeatedly overwritten for more than 106 cycles, the ratio of the ohmic values was about 100; and that the element works as a memory.

FIGS. 17 and 18 respectively show a result of having analyzed a relation of normal stress and shear stress around an edge part of an interface 13m between an interlayer insulation film 13 and a phase-change film 16, with an overetched amount d of the interlayer insulation film 13, while variously changing a plug diameter (the diameter of a bottom electrode) and a thickness (GST thickness) of the phase-change film, similarly to the above described result of stress analysis shown in the above described FIGS. 12 and 13, and show the dependency of the respective stress on the overetched amount d. A stress value when a distance from an edge part r=0.125 [μm] was used as a representative value of the stress value. The stresses were analyzed and determined in conditions of: widths of a nonvolatile memory device 19 of 200 [nm], 600 [nm] and 1,000 [nm]; thicknesses (GST thicknesses) of the phase-change film 16 of 50 [nm], 100 [nm] and 200 [nm]; a plug diameter (of an electroconductive plug 15) of 160 [nm]; a thickness of a top electrode 17 of 50 [nm]; a thickness of an insulating film 18 of 50 [nm]; and overetched amounts d of 0 [nm], 10 [nm], 20 [nm], 30 [nm], 40 [nm], 50 [nm] and 100 [nm]. It is known from a measurement result that a stress of about 100 [MPa] remains in the phase-change film 16 when the film is formed, so that in the analysis, similarly to the case of the above described stress analysis, 100 [MPa] was used as a stress of the phase-change film in an early stage.

Each stress of tungsten forming a top electrode 17 and a silicon oxide film forming an insulating film 18 in the early stage were set to 0 [MPa], because they can be adjusted by a film-forming condition. Even though these stress values changed, an effect of an overetching amount on the reduction of stress at an edge part is consistent, which will be described below.

As is shown in FIGS. 17 and 18, similarly to the result of the above described stress analysis, stress concentrates at an edge part remarkably when an interlayer insulation film 13 is not overetched, or equivalently, d=0. In contrast to this, when the interlayer insulation film 13 is overetched, the stress concentration at the edge part is reduced. It is clear from FIGS. 17 and 18 that normal stress and shear stress decrease with the increase of an overetched amount d, and that both values of the normal stress and the shear stress when the overetched amount is 20 [nm] are reduced into about ⅓ of the values when not overetched.

In addition, FIGS. 19 and 20 are diagrammatic drawings showing standardized values of stress values in FIGS. 17 and 18 by matching them to the maximum stress (stress at an overetched amount d=0). As is shown in FIGS. 19 and 20, even when a width of a nonvolatile memory device 19 and a thickness of GST vary, an effect of reducing stress by overetching is approximately constant at an overetched amount of 20 [nm], so that a suitable over-etching amount is about 20 [nm] in order to reduce the stress with a small over-etching amount.

In other words, the overetching for the interlayer insulation film 13 can reduce the stress concentration in the edge part of the interface between the interlayer insulation film 13 and the phase-change film, and can inhibit the peeling of the phase-change film. Particularly, in order to increase an effect of the stress reduction, the overetching amount of the interlayer insulation film 13 is preferably 20 [nm] or more.

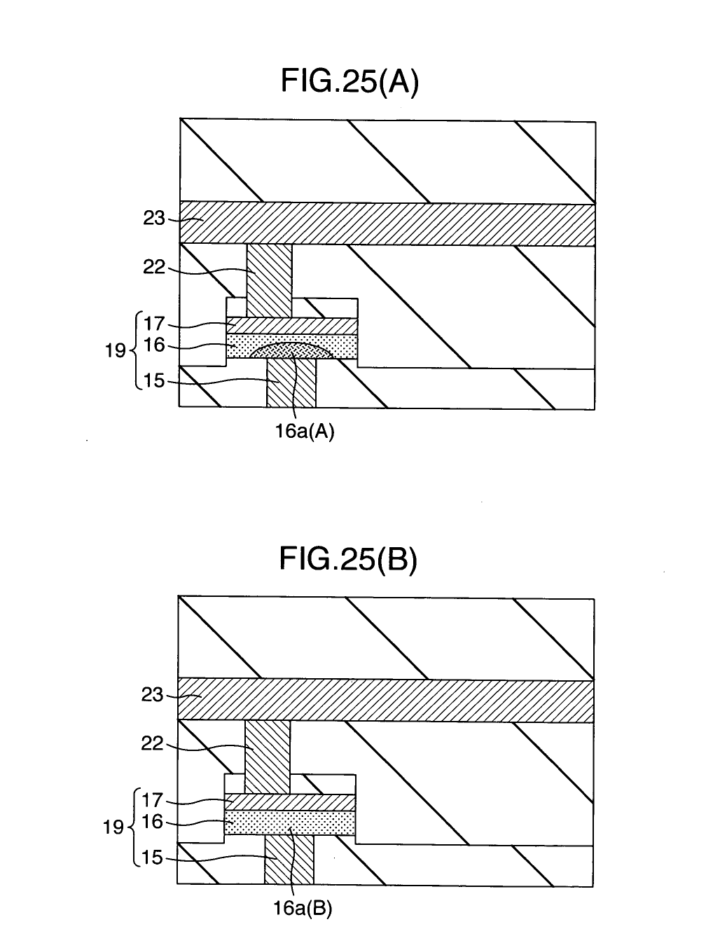

Here, operations of writing, erasing and reading of a memory cell Mc will be described a little more in detail with reference to FIG. 25. FIG. 25 is a view showing the vicinity of a nonvolatile memory device extracted from FIG. 1, FIG. 25(A) shows a state after a memory has been erased, and FIG. 25(B) shows a state after a memory has been written. Here, “writing of memory” means the operation of lowering resistance in a region (a memory storage portion 16a) of a phase-change film 16 around right above an electroconductive plug 15, by crystallizing the region; and “erasing of memory” means the operation of increasing the resistance in the memory storage portion 16a, by converting the state into an amorphous state.

(1) Erasing of Memory (Conversion to Amorphous)

The memory is erased by the steps of: applying a voltage of 1.5 [V] to a word line WL to turn a MISFET-Q “ON”; further applying a voltage of 1.5 [V] to a bit line 23 for 50 nsec; and then instantly dropping the voltage on the bit line 23 to 0 [V] (for instance, in 2 nsec which is a period of time while the voltage of the bit line is dropped from 1.5 [V] to 0 [V]). By dropping the voltage of the bit line 23 in the above described way, a temperature of the memory storage portion 16a is instantly lowered, and the memory storage portion 16a is solidified and becomes amorphous (an amorphous state—A), as shown in FIG. 25 (a). Thereby, specific resistance in the memory storage portion 16a increases. For instance, resistance in the memory storage portion 16a increases to 1 MΩ, and the state at this time is determined, for instance, as “0” bit.

(2) Writing of Memory (Crystallization)

The memory is written by the steps of: applying a voltage of 1.5 [V] to a word line WL to turn a MISFET-Q “ON”; further applying a voltage of 3.0 [V] to a bit line 23 for 1 μsec; and then dropping the voltage on the bit line 23 to 0 [V]. By applying a voltage of 3.0 [V] to the bit line 23 in the above described way, an electric current passes through a memory storage portion 16a of high resistance; generates Joule heat; raises a temperature of the memory storage portion 16a of a phase-change film 16 around right above an electroconductive plug 15 to a crystallization temperature; and crystallizes the memory storage portion 16a to change the state from an amorphous state to a crystal state (a crystal state—B), as shown in FIG. 25(B). Thereby, specific resistance in the memory storage portion 16a decreases. For instance, resistance in the memory storage portion 16a decreases to 10 kQ, and the state at this time is determined, for instance, as “1” bit.

(3) Method for Reading Memory

In order to read a memory, a voltage of 0.5 [V] is applied to a word line WL to turn a MISFET-Q “ON”, and further a voltage of 0.5 [V] is applied to a bit line 23 for 5 nsec. When a memory storage portion 16a is in an amorphous state A and has high resistance, a comparatively small drain current (for instance, 0.1 μA) passes through the memory storage portion. In contrast to this, when the memory storage portion 16a is in a crystal state B and has low resistance, a comparatively large drain current (for instance, 10 μA) passes through the memory storage portion. However, the drain current is not so large a value as to change a phase state (an amorphous state A or a crystal state B)) of the memory storage portion 16a.

Then, an amount of the above described drain current is detected through a sense amplifier. When an amperage is comparatively small (0.1 μA, for example), a bit of a memory storage portion 16a is “1”, and when the amperage is comparatively large (10 μA, for example), the bit of the memory storage portion 16a is

### Embodiment 2

In the present embodiment 2, an example will be described which employs an etching-stop film, for the purpose of enhancing the precision of the difference of height between an interface of an interlayer insulation film with a phase-change film and the surface of the interlayer insulation film around the phase-change film.

FIGS. 21 to 24 are schematic sectional views showing a process for producing a phase-change random access memory according to Embodiment 2 of the present invention.

At first, components up to a wire 12 is formed by the same steps as in the above described Embodiment 1, and then an interlayer insulation film 13 including an etching-stop film 13b in the film is formed as shown in FIG. 21. In the present embodiment 2, the interlayer insulation film 13 is not limited, but has an etching-stop film 13b between the insulating films 13a and 13c. The insulating films 13a and 13c are, for instance, made of a silicon oxide film, and the etching-stop film 13b is, for instance, made of a silicon nitride film which can assume an etching ratio (have selectivity) with respect to a silicon oxide film. These films (13a, 13b and 13c) are sequentially formed on the interlayer insulation film 9 so as to cover the wire 12, for instance, with a CVD method.

An insulating film 13c preferably has a thickness of 20 [nm] or thicker, because the thickness affects a difference of height (an offset in a thickness direction of a substrate 1) between an interface 13m of an interlayer insulation film 13 with a phase-change film 16 and the surface of the interlayer insulation film 13 around the phase-change film 16.

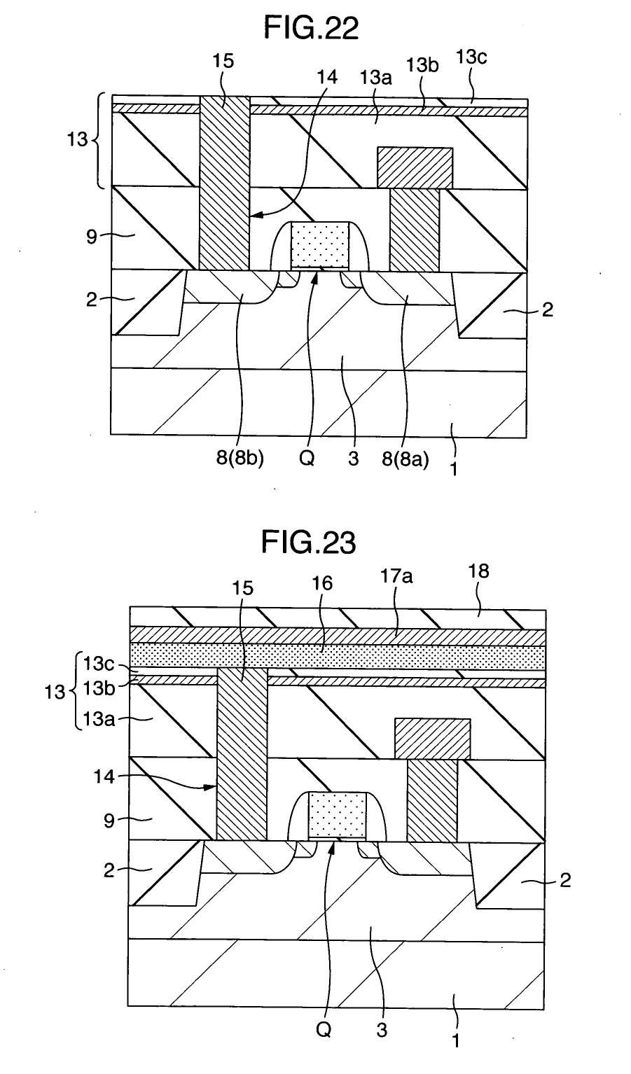

Subsequently, a process for producing a phase-change random access memory continues the steps of: forming a connection hole 14 (cf. FIG. 22) reaching an n-type semiconductor region 8b on the other n-type semiconductor region 8b of a MISFET-Q from the surface of an interlayer insulation film 13 (an insulating film 13c); and then selectively embedding an electroconductive plug 15 in the connection hole 14, as shown in FIG. 22:

as shown in FIG. 23, sequentially forming a phase-change film 16 made of a germanium-antimony-tellurium compound (Ge₂Sb₂Te₅) on the interlayer insulation film 13 including an electroconductive plug 15, for instance, with a sputtering method; a top electrode film 17a made of tungsten (W), for instance, with a sputtering method; and an insulating film 18 made of a silicon oxide film, for instance, by a CVD method: and

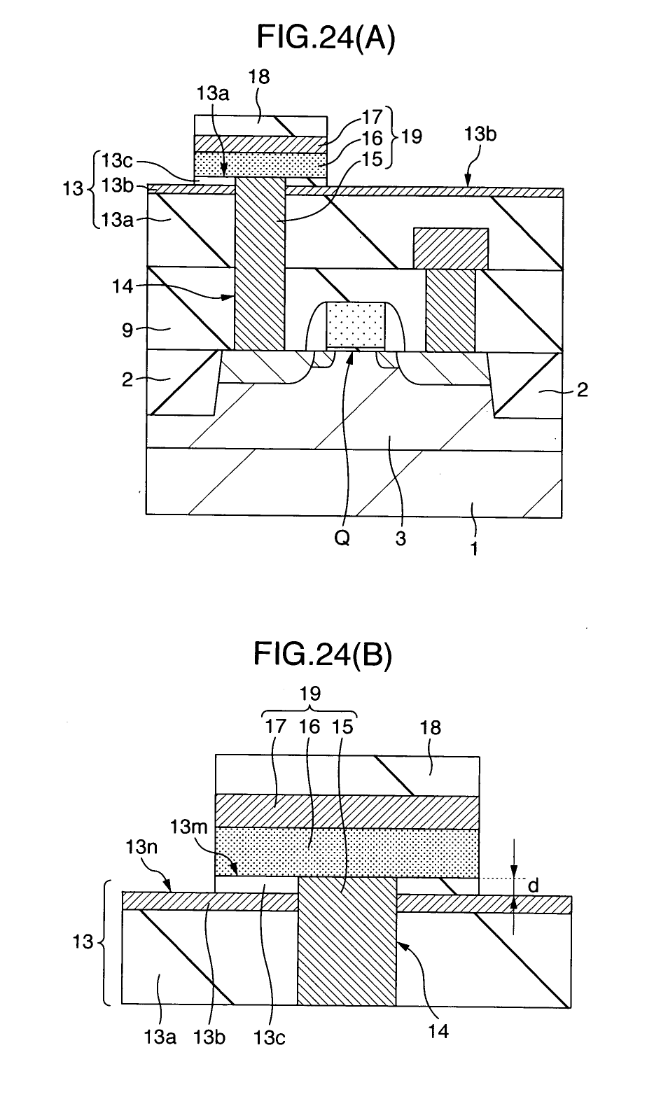

sequentially patterning an insulating film 18, a top electrode film 17a and a phase-change film 16 by dry etching, as shown in FIGS. 24((A) and (B)). Through the above steps, a nonvolatile memory device 19 is formed which has the bottom electrode of an electroconductive plug 15 embedded in interlayer insulation films 9 and 13, a phase-change film 16 provided on the interlayer insulation film 13 so as to cover the bottom electrode, and a top electrode 17 that is made of a top electrode film 17a, and is provided on the phase-change film 16 so as to cover the phase-change film 16.

An insulating film 18 is patterned by forming an etching mask on an insulating film 18, for instance, with a photolithography technology, and removing the insulating film 18 around the etching mask by etching. A top electrode film 17a is patterned by removing the top electrode film 17a around the patterned insulating film 18 by etching. A phase-change film 16 is patterned by removing the phase-change film 16 around the pattered top electrode film 17a (a top electrode) by etching.

In the above described dry etching step, as shown in FIG. 24(B), an insulating film 13c of an interlayer insulation film 13 is over-etched, and the insulating film 13c around a phase-change film 16 is removed. By removing the insulating film 13c around the phase-change film 16 by overetching as described above, a forming angle 9 of an interlayer insulation film 13 at an edge part of an interface 13m between the phase-change film 16 and the interlayer insulation film 13 (the insulating film 13c) is less than 180 degrees. In an example shown in FIG. 24(B), the above described forming angle θ is approximately 90 degrees. Because the above described forming angle θ is less than 180 degrees, stress acting around the edge part of the interface 13m between the interlayer insulation film 13 and the phase-change film 16 can be reduced to inhibit the peeling of the phase-change film 16 (to improve an adhesion), in the present embodiment 2 as well.

The present embodiment 2 also adopts the method of etching the surface of the interlayer insulation film 13 around a phase-change film 16 when patterning the phase-change film 16, to overetch it, as a method of offsetting (positioning) the surface of the interlayer insulation film 13 around the phase-change film 16 to a position located to a more substrate 1 side than an interface 13m between the interlayer insulation film 13 and the phase-change film 16 is. Accordingly, the surface 13n after the interlayer insulation film 13 around the phase-change film 16 has been overetched, is formed so as to conform to a perimeter of the phase-change film 16.

By the way, in the above described embodiments 1 and 2, the method of continuously etching the surface of an interlayer insulation film 13 around a phase-change film 16 when patterning the phase-change film 16, to overetch it, as the example of a method of offsetting (positioning) the surface of the interlayer insulation film 13 around the phase-change film 16 to a position located to a more substrate 1 side than an interface 13m between the interlayer insulation film 13 and the phase-change film 16 is, but the surface of the interlayer insulation film 13 around the phase-change film 16 may be etched, with a different etching process from that used for patterning the phase-change film 16. In the upshot, it is essential only that the surface of the interlayer insulation film 13 around the phase-change film 16 is positioned to a more substrate 1 side than the interface 13m between the interlayer insulation film 13 and the phase-change film 16. However, the method of continuously etching the surface of the interlayer insulation film 13 around the phase-change film 16 when patterning the phase-change film 16, to overetch it, can position the surface of the interlayer insulation film 13 around the phase-change film 16 to a more substrate 1 side than the interface 13m between the interlayer insulation film 13 and the phase-change film 16 is positioned, without increasing the number of production steps.

In addition, in the above described embodiment 2, a method of using a silicon nitride film as an example of an etching-stop film 13b was described, but the etching-stop film 13b does not need to be particularly limited to the silicon nitride film, as long as it is an insulating film capable of assuming a selection ratio with respect to the insulating film 13c. The etching-stop film 13b may employ, for instance a SiC (silicon carbide) film, an AlO (aluminum oxide) film or the like.

In addition, in the above described embodiments 1 and 2, a method of positioning the surface 13n of an interlayer insulation film 13 around a phase-change film 16 to a more substrate side than an interface 13m between the interlayer insulation film 13 and the phase-change film 16 is positioned, was described as an example of the method of reducing stress concentrated on an edge part of the interface 13m, but a groove having some width may be formed on the interlayer insulation film 13 so as to surround the patterned phase-change film 16, or equivalently, to surround the interface 13m. The groove can also reduce the stress concentrated on the edge part of the interface 13m.

The invention achieved by the present inventors has been specifically described above, on the basis of the above described embodiments, but the present invention is not limited to the above described embodiments, and can be variously changed in a range of undeviating from the point, as a matter of course.

1. A process for producing a phase-change random access memory comprising the steps of:
(a) forming a bottom electrode embedded in an insulating film on a substrate;
(b) forming a phase-change film which has different specific resistance values from each other depending on the phase, on the insulating film so as to cover the bottom electrode;
(c) forming an electroconductive film on the phase-change film;
(d) etching the electroconductive film and forming a top electrode on the bottom electrode;
(e) after the step (d), removing the phase-change film existing around the top electrode by etching; and
(f) after the step (e), etching the film around the phase-change film to position the surface of the insulating film around the phase-change film to a more substrate side than an interface between the insulating film and the phase-change film is positioned.

2. The process for producing the phase-change random access memory according to claim 1, wherein the steps (e) and (f) are continually performed.

3. The process for producing the phase-change random access memory according to claim 1, wherein the surface of the insulating film around the phase-change film is formed so as to conform to the phase-change film.

4. The process for producing the phase-change random access memory according to claim 1, wherein the etching amount of the insulating film is 20 nm or more.

5. The process for producing the phase-change random access memory according to claim 1, wherein the phase-change film is made of a material mainly containing a germanium-antimony-tellurium compound.

6. The process for producing the phase-change random access memory according to claim 1, wherein the insulating film contains an etching-stop film therein.

7. A phase-change random access memory having a bottom electrode provided so as to be embedded in an insulating film on a substrate, a phase-change film which can assume different specific resistance values from each other depending on the phase and is provided on the insulating film so as to cover the bottom electrode, and a top electrode provided on the phase-change film, wherein the surface of the insulating film around the phase-change film is positioned to a more substrate side than an interface with the phase-change film is.

8. The phase-change random access memory according to claim 7, wherein the surface of the insulating film existing around the phase-change film is formed so as to conform to the phase change film.

9. The phase-change random access memory according to claim 7, wherein the difference of the height between an interface of the insulating film with the phase-change film and the surface of the insulating film in the interface side around the phase-change film is 20 nm or more.

10. The phase-change random access memory according to claim 7, wherein the phase-change film is made of a material mainly containing a germanium-antimony-tellurium compound.
